(19) United States
(12) Patent Application Publication
(10) Pub. No.: US 2024/0218561 A1
(43) Pub. Date: Jul. 4, 2024

(54) THIN-FILM DEPOSITION APPARATUS

(71) Applicant: Samsung Electronics Co., Ltd., Suwon-si (KR)

(72) Inventors: Janghwi Lee, Suwon-si (KR); Yeontae Kim, Suwon-si (KR); Junbum Park, Suwon-si (KR); Hunyong Park, Suwon-si (KR); Suhwan Park, Suwon-si (KR); Sangwoo Bae, Suwon-si (KR); Motoshi Sakai, Suwon-si (KR); Wondon Joo, Suwon-si (KR); Jaeho Jin, Suwon-si (KR)

(21) Appl. No.: 18/515,664

(22) Filed: Nov. 21, 2023

(30) Foreign Application Priority Data
Dec. 29, 2022 (KR) 10-2022-0189382

(51) Int. Cl. C30B 25/16; C30B 25/12

(52) U.S. Cl. CPC C30B 25/16; C30B 25/12

(57) ABSTRACT

A thin-film deposition apparatus includes: a housing; a chamber located within the housing and providing an internal space; a platform disposed within the chamber and configured to support a substrate; a reflector disposed within the housing and disposed outside the chamber; a light source disposed between opposing walls of the reflector and configured to radiate light onto the substrate; a light receiver disposed within the housing, spaced apart from the light source with a portion of the reflector therebetween, and having a hole through which light emitted from the substrate is introduced; an optical cable connected to the light receiver and extending to the outside of the housing; and a sensor disposed outside the housing, connected to the optical cable, and configured to measure a temperature of the substrate by analyzing light transmitted from the optical cable.

### CROSS-REFERENCE TO RELATED APPLICATION

This application is based on and claims priority under 35 U.S.C. §119 to Korean Patent Application No. 10-2022-0189382, filed on Dec. 29, 2022, in the Korean Intellectual Property Office, the disclosure of which is incorporated by reference herein in its entirety.

### BACKGROUND

The inventive concept relates to a thin-film deposition apparatus, and more particularly, to a thin-film deposition apparatus with increased substrate temperature measurement accuracy.

In general, a semiconductor device may be manufactured through a plurality of unit processes. The unit processes may include a thin-film deposition process, a diffusion process, a heat treatment process, a photolithography process, a polishing process, an etching process, an ion implantation process, and a cleaning process. Among them, the thin-film deposition process may be a process of forming a thin film on a substrate. The thin film may be formed to be monocrystalline, polycrystalline, or amorphous. Monocrystalline thin films may have a lower density of lattice defects than polycrystalline and amorphous thin films.

### SUMMARY

Aspects of the inventive concept provide a thin-film deposition apparatus capable of precisely measuring the temperature of a substrate during a thin-film deposition process.

In addition, the issues to be addressed by the technical idea of the inventive concept are not limited to those mentioned above, and other issues may be clearly understood by those of ordinary skill in the art from the following descriptions.

According to an aspect of the inventive concept, a thin-film deposition apparatus includes: a housing; a chamber located within the housing and providing an internal space; a platform disposed within the chamber and configured to support a substrate; a reflector disposed within the housing and disposed outside the chamber; a light source disposed between opposing walls of the reflector and configured to radiate light onto the substrate; a light receiver disposed within the housing, spaced apart from the light source with a portion of the reflector therebetween, and having a hole through which light emitted from the substrate is introduced; an optical cable connected to the light receiver and extending to the outside of the housing; and a sensor disposed outside the housing, connected to the optical cable, and configured to measure a temperature of the substrate by analyzing light transmitted from the optical cable.

According to an aspect of the inventive concept, there is provided a thin-film deposition apparatus including: a housing; a chamber located within the housing and providing an internal space; a susceptor disposed within the chamber and supporting a substrate; a reflector disposed within the housing and disposed outside the chamber; a light source disposed to be surrounded by the reflector and configured to radiate light onto the substrate; a first temperature measuring device configured to measure a temperature of the substrate and including a first light receiver, a first optical cable, and a first sensor; and a second temperature measuring device configured to measure the temperature of the substrate, wherein the first light receiver is disposed within the housing, is spaced apart from the light source with the reflector therebetween, and has a hole through which light emitted from the substrate is introduced, the first optical cable extends outside the housing to connect the first light receiver to the first sensor, and the first sensor is disposed outside the housing and configured to measure the temperature of the substrate by analyzing light transmitted from the first optical cable.

According to an aspect of the inventive concept, there is provided a thin-film deposition apparatus including: a housing; a chamber disposed within the housing and providing an internal space; a susceptor disposed within the chamber and supporting a substrate; a reflector disposed within the housing and disposed outside the chamber; a light source unit disposed within the reflector and configured to radiate light onto the substrate; a first temperature measuring device configured to measure a temperature of the substrate and including a first light receiver, a first optical cable, and a first sensor unit; a second temperature measuring device configured to measure the temperature of the substrate and located within the housing; and a cooling device installed in the second temperature measuring device and configured to adjust a temperature of the second temperature measuring device, wherein the first light receiver is disposed within the housing, is spaced apart from the light source unit with the reflector therebetween, and has a hole through which light emitted from the substrate is introduced, a sidewall forming the hole is coated with a reflective metal, and a horizontal width of the hole decreases as it approaches the first optical cable, the first optical cable extends outside the housing to connect the first light receiver to the first sensor unit, and the first sensor unit is disposed outside the housing and configured to measure the temperature of the substrate by analyzing light of consecutive wavelengths, transmitted from the first optical cable.

### BRIEF DESCRIPTION OF THE DRAWINGS

Embodiments will be more clearly understood from the following detailed description taken in conjunction with the accompanying drawings in which:

FIG. 1 is a schematic cross-sectional view of a thin-film deposition apparatus according to an embodiment;

FIG. 2 is a view illustrating a process in which light reaches a sensor unit in FIG. 1;

FIG. 3 is a conceptual diagram schematically illustrating a sensor unit of a thin-film deposition apparatus according to an embodiment;

FIG. 4 is a schematic cross-sectional view of a thin-film deposition apparatus according to an embodiment;

FIG. 5 is a schematic cross-sectional view of a thin-film deposition apparatus according to an embodiment;

FIG. 6 is a schematic cross-sectional view of a thin-film deposition apparatus according to an embodiment;

FIG. 7 is a schematic cross-sectional view of a thin-film deposition apparatus according to an embodiment;

FIG. 8 is a schematic cross-sectional view of a thin-film deposition apparatus according to an embodiment;

FIG. 9 is a schematic cross-sectional view of a thin-film deposition apparatus according to an embodiment;

FIG. 10 is a schematic cross-sectional view of a thin-film deposition apparatus according to an embodiment; and

FIG. 11 is a flow chart showing an example method of manufacturing a semiconductor device, according to one embodiment.

### DETAILED DESCRIPTION OF THE EMBODIMENTS

Because the present embodiments may have various changes and various forms, some embodiments will be illustrated in the drawings and described in detail. However, this is not intended to limit the present embodiments to a certain disclosure.

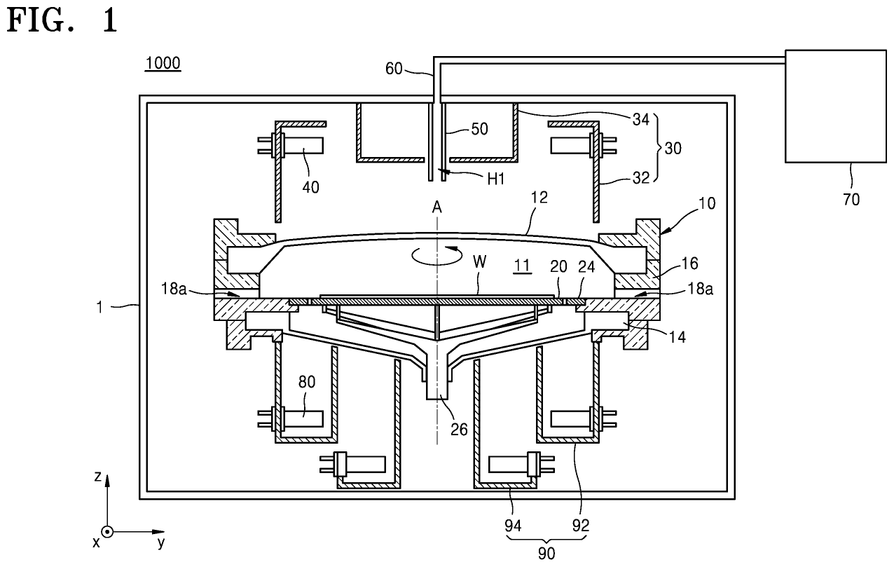

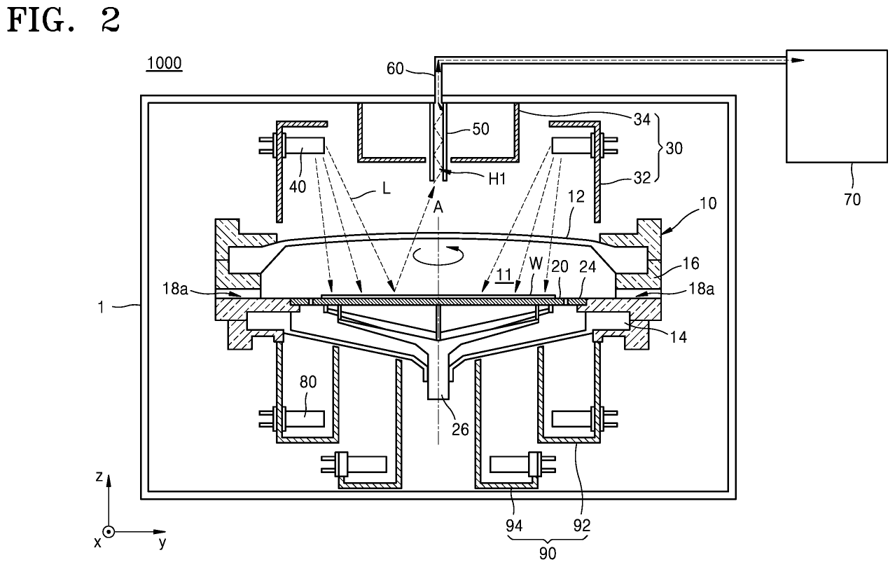

FIG. 1 is a schematic cross-sectional view of a thin-film deposition apparatus 1000 according to an embodiment. FIG. 2 is a view illustrating a process in which light reaches a sensor unit in FIG. 1. FIGS. 1 and 2 depict certain components of the various embodiments for emphasis and leave out other components that are also part of the overall apparatus. For example, various frames, connectors, and other components would be included to position the described components in the relative locations described herein.

Referring to FIGS. 1 and 2, the thin-film deposition apparatus 1000 may include a housing 1, a chamber 10, a susceptor 20, a reflector 30, a light source unit 40, a light receiver 50, an optical cable 60, and a sensor unit 70. Optionally, the thin-film deposition apparatus 1000 may further include a lower reflector 90 and a lower light source unit 80. Items described in the singular herein may be provided in plural, as can be seen, for example, in the drawings. Thus, the description of a single item that is provided in plural may apply to the remaining plurality of items. In some embodiments, the thin-film deposition apparatus 1000 may be a lamp type epitaxy deposition apparatus.

The housing 1 may include the chamber 10, the susceptor 20, the reflector 30, the light source unit 40, and the light receiver 50 therein. The housing 1 may protect the chamber 10, the susceptor 20, the reflector 30, the light source unit 40, and the light receiver 50 from the outside. The housing may be formed, for example, of a top face forming a top surface, a bottom face forming a bottom surface, and sidewalls, or side surfaces, that form an enclosed space.

The chamber 10 may be disposed within housing 1. The chamber 10 provides an internal space 11 in which a thin-film deposition process is performed on a substrate W. The internal space 11 may be controlled in a vacuum state. The chamber 10 may include an upper chamber 12, a lower chamber 14, and an edge ring 16. The upper chamber 12, the lower chamber 14, and the edge ring 16 may be coupled to each other to form the internal space 11.

The upper chamber 12 and the lower chamber 14 may be provided in a dome shape. Alternatively, the lower chamber 14 may have a funnel shape. The upper chamber 12 and the lower chamber 14 may include a transparent material. For example, the upper chamber 12 and the lower chamber 14 may include quartz or glass.

The edge ring 16 may surround the edges of the upper chamber 12 and the lower chamber 14 and join the upper chamber 12 and the lower chamber 14 together. For example, the upper chamber 12 and the edge ring 16 may be mechanically coupled to each other via an upper clamp ring.

When the substrate W is loaded/unloaded into/from the internal space 11, at least one of the upper chamber 12 and the lower chamber 14 may be separated from the edge ring 16. For example, the substrate W may be loaded/unloaded through a slit door (not shown) provided in the edge ring 16. Alternatively, the edge ring 16 may be separated vertically.

The edge ring 16 may have a gas inlet 18a and a gas outlet 18b. For example, the edge ring 16 may have grooves connecting the inside of the chamber 10 to the outside thereof, and each of the grooves may serve as the gas inlet 18a and the gas outlet 18b. The gas inlet 18a may be formed on one side of the edge ring 16 and the gas outlet 18b may be formed on the other side of the edge ring 16.

The gas inlet 18a and the gas outlet 18b may be provided at opposite positions to each other. Process gas may be provided into the chamber 10 through the gas inlet 18a. When a process is completed, the process gas may be discharged to the outside of the chamber 10 through the gas outlet 18b. The process gas may include, for example, silane (SiH₄), disilane (Si₂H₆), DCS (SiH₂Cl₂), or TCS (SiHCl₃).

The susceptor 20 is disposed within the chamber 10. Specifically, the susceptor 20 is disposed within the internal space 11. The susceptor 20 may be a platform or stage that supports and rotate the substrate W. The susceptor 20 may include a graphite material or ceramic material coated with a silicon material, such as silicon carbide, or other process resistant material.

A preheating ring 24 may be provided to surround the susceptor 20. The preheating ring 24 may preheat the process gas to a certain temperature. Due to this, the process gas may be thermally decomposed into a gaseous form for single crystal growth.

A support 26 may support the susceptor 20. The support 26 may elevate the susceptor 20 and rotate the susceptor 20 about a central axis A of the substrate W. For example, the susceptor 20 may rotate the substrate W at about 10 rpm to about 100 rpm. As the susceptor 20 rotates, uniform processing may be performed on the entire area of the substrate W.

The reflector 30 may be disposed within the housing 1. The reflector 30 may be disposed on an outer upper portion of the chamber 10. The reflector 30 may cover the upper chamber 12. The reflector 30 may include a first sub-reflector 32 and a second sub-reflector 34. The first sub-reflector 32 and the second sub-reflector 34 may be coupled to each other. The reflector 30 is shown in a cross-sectional view, but in a plan view or perspective view, the sub-reflector 32 may have sidewalls that surround the substrate W from a plan view. For example, the sub-reflector 32 may have a cylindrical sidewall shape, and an annular top surface. Other shapes may be employed. The sub-reflector 32 may have sidewalls opposite each other. The sub-reflector 34 may be formed to have sidewalls that surround the light receiver 50. For example, the sub-reflector 34 may have a cylindrical sidewall shape, and an annular bottom surface. The surfaces of the sub-reflector 32 and sub-reflector 34 may be vertical and horizontal, as depicted in FIG. 1, or in other embodiments, may have other angles to reflect light toward the substrate W. The sub-reflector 34 and sub-reflector 32 may be connected to each other by additional components such as additional housing components, frame components, and plates, which are not shown.

The first sub-reflector 32 and the second sub-reflector 34 provide a space in which light emitted from the light source unit 40 is reflected. The reflector 30 may reflect light such that the light emitted by the light source unit 40 is radiated to a desired location, such as the substrate W, the susceptor 20, or the preheating ring 24. The reflector 30 may focus the light emitted by the light source unit 40 on the substrate W. The reflector may be formed of a hard material and an inside of the reflector 30 (e.g., portion facing or reflecting light that eventually arrives at the substrate W) may be coated with a material having high reflectivity.

The light source unit 40 may be disposed within the reflector 30. In some embodiments, a plurality of light source units 40 may be provided. When the plurality of light source units 40 are provided, they may be arranged in a circumferential direction of the reflector 30. Each light source unit 40 may be a halogen lamp, for example, and may be described as a light source.

The substrate W may be heated by radiating light from the light source unit 40 to the substrate W. The light radiated by the light source unit 40 may be absorbed by the substrate W, the susceptor 20, and the preheating ring 24 and converted into thermal energy. The light radiated by the light source unit 40 may include infrared rays.

The light radiated by the light source unit 40 may directly pass to the upper chamber 12 and be introduced into the internal space 11, to be received at the substrate W, the susceptor 20, and the preheating ring 24 without being reflected by the reflector 30. For example, a ceiling of the upper chamber 12 may be formed of a transparent material, through which the light radiated by the light source unit 40 passes. In addition, the light radiated by the light source unit 40 may be reflected by the reflector 30 and may be introduced into the internal space 11 after passing through the upper chamber 12. Therefore some light from the light source unit 40 may reach the substrate W, the susceptor 20, and the preheating ring 24 without being reflected by the reflector 30, and some light from the light source unit 40 may reach the substrate W, the susceptor 20, and the preheating ring 24 after being reflected by the reflector 30.

The light receiver 50 may be disposed within the housing 1. The light receiver 50 may be spaced apart from the light source unit 40 with the reflector 30 therebetween. Therefore, the light radiated by the light source unit 40 may not be directly introduced into the light receiver 50.

At least some of light reflected or emitted from the substrate W may be introduced into the light receiver 50. The light receiver 50 may include a hole H1. Light reflected or emitted from the substrate W may be introduced into the hole H1. The hole HI may provide a path through which light reflected or emitted from the substrate W moves to the optical cable 60.

In some embodiments, the light receiver 50 may be located above the chamber 10. For example, the light receiver 50 may be spaced apart from the light source unit 40 with the reflector 30 positioned above the chamber 10 therebetween. Light reflected from the upper surface of the substrate W may be introduced into the hole H1 of the light receiver 50.

In some embodiments, the light receiver 50 may be located below the chamber 10. For example, the light receiver 50 may be spaced apart from the lower light source unit 80 with the lower reflector 90 therebetween. Therefore, light reflected or emitted from the lower surface of the substrate W may be introduced into the light receiver 50.

In some embodiments, a sidewall forming the hole H1 of the light receiver 50 may be coated with metal. More generally, the sidewall forming the hole HI may be coated with a material having high reflectivity for introduced light. In some embodiments, the sidewall may be coated with gold.

The optical cable 60 may be connected to the light receiver 50. Specifically, the optical cable 60 may be connected to the hole HI of the light receiver 50. The optical cable 60 may extend to the outside of the housing 1. That is, the optical cable 60 may provide a path through which light introduced into the light receiver 50 is transferred to the outside of the housing 1.

In some embodiments, the optical cable 60 may be a hollow fiber. For example, the optical cable 60 may be a cable including a hollow portion. Light introduced into the optical cable 60 may pass through the hollow portion and be incident on the sensor unit 70.

In some embodiments, the hollow portion of the optical cable 60 may be coated with a material having high infrared reflectivity. Specifically, the hollow portion of the optical cable 60 may be coated with metal. For example, the sidewall of the hollow portion of the optical cable 60 may be coated with gold.

In some embodiments, the optical cable 60 may be a light pipe. The light pipe may transmit light to the sensor unit 70 by using a non-convergence method or a reflection method.

The sensor unit 70 may be located outside the housing 1. The sensor unit 70 may be spaced apart from the light source unit 40 with the housing 1 therebetween. Specifically, heat generated by the light source unit 40 may be blocked by the housing 1 and may not reach the sensor unit 70. In other words, when measuring the temperature of the substrate W, the temperature of the sensor unit 70 may not substantially change due to the light source unit 40.

The sensor unit 70 may be connected to the optical cable 60. The optical cable 60 may transmit light collected by the light receiver 50 to the sensor unit 70. The sensor unit 70 may analyze light transmitted from the optical cable 60. In some embodiments, the sensor unit 70 may measure the temperature of the substrate W by analyzing the light collected by the light receiver 50.

In some embodiments, the sensor unit 70 may include or be an optical spectrum analyzer (OSA) or similar device that can determine the same information. The OSA may analyze light with multiple wavelengths. For example, the OSA may analyze light of consecutive wavelengths and indicate the amount of light at each wavelength. The sensor unit 70 may include hardware, such as one or more processors, memory, and various logic circuits, and computer program code configured to analyze the light transmitted from the optical cable 60 to measure the temperature of the substrate W.

Specifically, the sensor unit 70 may select at least three wavelengths among consecutive wavelengths to obtain the temperature and reflected energy of the substrate. For example, the temperature and reflected energy of the substrate W may be obtained through a temperature-wavelength relational expression I(λ, T)=ϵ·I(λ,T)+ρR. Here, I represents the amount of light, ϵ represents the emissivity, λ represents the wavelength, T represents the temperature, p represents the sum of reflectance and transmittance, and R represents the reflected energy.

In this case, the closer the selected wavelengths are, the smaller the difference in emissivity generated at each wavelength may be. Therefore, the closer the values of the selected three wavelengths are, the more accurate the measured values of the temperature and reflected energy of the substrate may be.

In some embodiments, the sensor unit 70 may select 1.45 μm as a first wavelength, 1.6 μm as a second wavelength, and 1.75 μm as a third wavelength. When the first to third wavelengths are substituted into the temperature-wavelength relational expression, the emissivity is substantially the same, and thus the temperature and reflected energy of the substrate may be obtained.

FIG. 2 shows a process in which light L radiated from the light source unit 40 is introduced into the sensor unit 70. For example, the light L radiated from the light source unit 40 may heat the substrate W and be reflected. At least portions of light L reflected from the substrate W and light L emitted from the substrate W may be directed toward the light receiver 50. Light L emitted from the substrate W may refer to the light L reflected from the substrate W or to light generated at the substrate W (e.g., it may include infrared light created by a reflection and/or by other heat generated at the substrate W).

Light L directed toward the light receiver 50 may be introduced into the hole H1 and moved through the optical cable 60. In this case, because the sidewall (e.g., an internal sidewall) forming the hole H1 is coated with a material having high reflectivity, the light introduced into the hole H1 may be reflected from the sidewall and incident on the optical cable 60.

Light L incident on the light receiver 50 may move to the outside of the housing 1 along the optical cable 60 and be transmitted to the sensor unit 70 located outside the housing 1. In this case, the optical cable 60 may include a hollow fiber whose inner wall is coated with a material having high reflectivity.

Optionally, the thin-film deposition apparatus 1000 may additionally include the lower reflector 90 and the lower light source unit 80. The lower reflector 90 may include a first lower reflector 92 and a second lower reflector 94. The lower light source unit 80 may be provided within the lower reflector 90.

The lower reflector 90 may include the same material as the reflector 30 and may have a function that is substantially the same as or similar to that of the reflector 30. The lower light source unit 80 may have a shape and a function that are substantially the same as or similar to those of the light source unit 40. The lower reflector 90 and the lower light source unit 80 may be omitted.

Light L reflected or emitted from the substrate W may be incident on the sensor unit 70, disposed outside the housing 1, through the light receiver 50 and the optical cable 60. Therefore, the light L reflected or emitted from the substrate W may be analyzed outside the housing 1. The temperature measurement accuracy of the sensor unit 70 may increase by analyzing the light L reflected or emitted from the substrate W from the outside of the housing 1.

The temperature measurement accuracy of the sensor unit 70 may vary depending on the temperature of the sensor unit 70. For example, if a sensor unit is place within the housing 1, the sensor unit may be heated by the light source units inside the housing 1. However, in the thin-film deposition apparatus 1000 according to the present embodiment, the light source unit 40 and the sensor unit 70 may be spaced apart from each other and the sensor unit 40 may be outside the housing 1, and thus the temperature of the sensor unit 70 may be kept constant. Accordingly, the temperature measurement performance and the reflected energy measurement performance of the sensor unit 70 may increase.

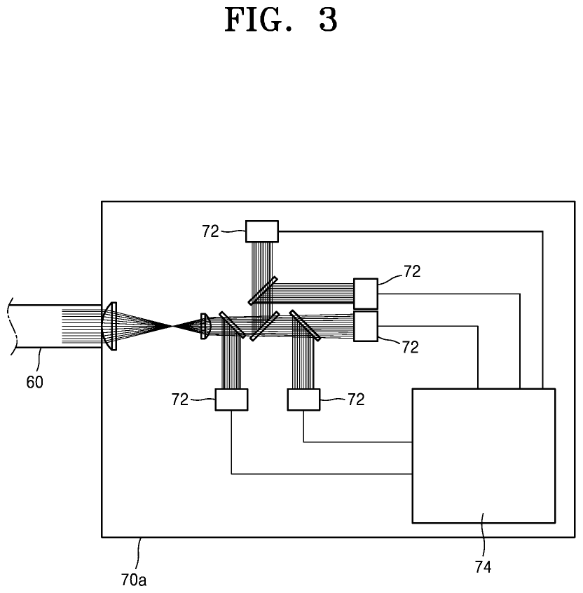

FIG. 3 is a conceptual diagram schematically illustrating a sensor unit 70a of the thin-film deposition apparatus 1000 according to an embodiment.

Referring to FIG. 3, the sensor unit 70a may include a multi-channel pyrometer. The multi-channel pyrometer may include a head 72 and an analyzer 74. The head 72 may include a plurality of lenses and a plurality of sensors.

Specifically, light having multiple wavelengths introduced into the sensor unit 70a may be separated for each certain wavelength through the plurality of lenses in the head 72. Light including only a certain wavelength may be introduced into different sensors and the amount of light may be measured. For example, the plurality of sensors may measure the amount of light of different wavelengths.

The amount of light measured by the head 72 may be transmitted to the analyzer 74. The analyzer 74 may measure the temperature and reflected energy of a substrate through the amount of light at a certain wavelength. For example, the temperature and reflected energy of the substrate may be measured through the temperature-wavelength relational expression. The analyzer 74 may include hardware and computer program code configured to perform calculations and analysis to determine the temperature and reflected energy of the substrate.

The temperature measurement accuracy of the sensor unit 70a may be improved by separating the light source unit 40, which increases the temperature of the substrate, from the sensor unit 70a that measures the temperature of the substrate. For example, while the sensor unit 70a measures the temperature of the substrate, the temperature of the sensor unit 70a may not change due to the light source unit 40. Accordingly, the temperature measurement accuracy of the sensor unit 70a may increase.

In addition, the sensor unit 70a may include a plurality of sensors and an analyzer 74 to measure the amount of light of various wavelengths through a single pyrometer.

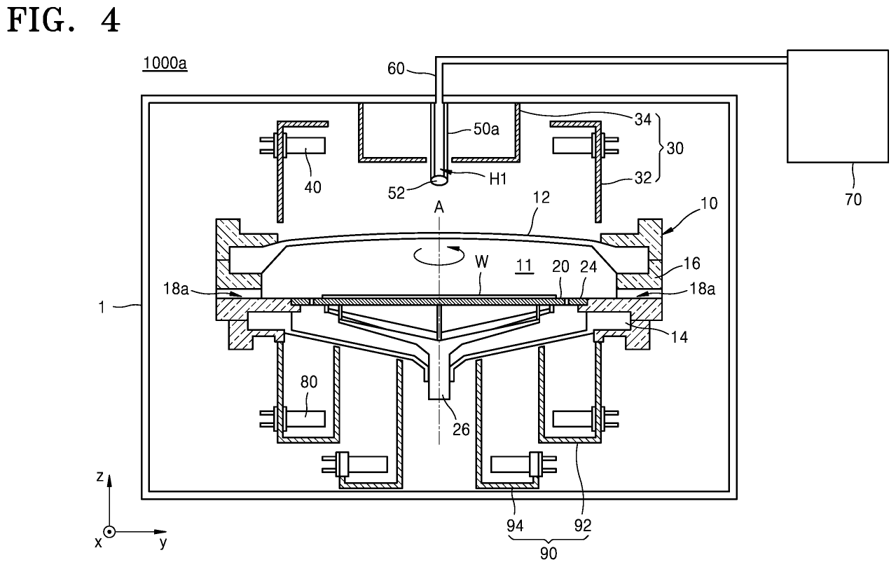

FIG. 4 is a schematic cross-sectional view of a thin-film deposition apparatus 1000a according to an embodiment.

Referring to FIG. 4, the thin-film deposition apparatus 1000a may include a housing 1, a chamber 10, a susceptor 20, a reflector 30, a light source unit 40, a light receiver 50a, an optical cable 60, and a sensor unit 70.

Optionally, the thin-film deposition apparatus 1000a may further include a lower reflector 90 and a lower light source unit 80.

Hereinafter, descriptions of the thin-film deposition apparatus 1000a that are redundant with those of the thin-film deposition apparatus 1000 of FIG. 1 will be omitted, and differences will be described.

The light receiver 50a of the thin-film deposition apparatus 1000a may further include a lens 52. In an embodiment, the sensor unit 70 may be the OSA or multi-channel pyrometer described above.

The lens 52 may be located at an entrance of a hole H1 of the light receiver 50a. That is, the lens 52 may be located on a path of light introduced into the hole H1. Therefore, light reflected or emitted from a substrate W may pass through the lens 52 and be introduced into the hole H1 of the light receiver 50a.

The lens 52 may transmit light emitted by the light source unit 40. For example, the lens 52 may transmit at least some of the wavelengths of light emitted from the light source unit 40. In some embodiments, the lens 52 may be a clear lens. The lens 52 is not limited thereto, and the lens 52 may be a lens capable of transmitting all wavelengths of light emitted from the light source unit 40.

The lens 52 may prevent contamination of the inside of the light receiver 50a. For example, the lens 52 may suppress a phenomenon in which foreign materials are introduced into the light receiver 50a. By using the lens 52, the life of the light receiver 50a may be extended.

Light passing through the lens 52 may be refracted. The lens 52 may be a convex lens or a concave lens. Light passing through the lens 52 may be refracted and be incident on the sidewall of the hole H1. The incident angle of light may be adjusted through the lens 52. By adjusting the incident angle through the lens 52, reflection may be minimized until light incident on the light receiver 50a is introduced into the optical cable 60.

Whenever light is reflected by a sidewall, noise and loss may occur in the light. Accordingly, by minimizing the number of reflections on the sidewall, light with less noise may be transmitted to the optical cable 60.

In the thin-film deposition apparatus 1000a according to the present embodiment, the temperature measurement accuracy of the sensor unit 70 may be improved by separating the light source unit 40, which increases the temperature of the substrate W, from the sensor unit 70 that measures the temperature of the substrate W. That is, while the sensor unit 70 measures the temperature of the substrate W, the temperature of the sensor unit 70 may not change due to the light source unit 40. Accordingly, the temperature measurement accuracy of the sensor unit 70 may increase.

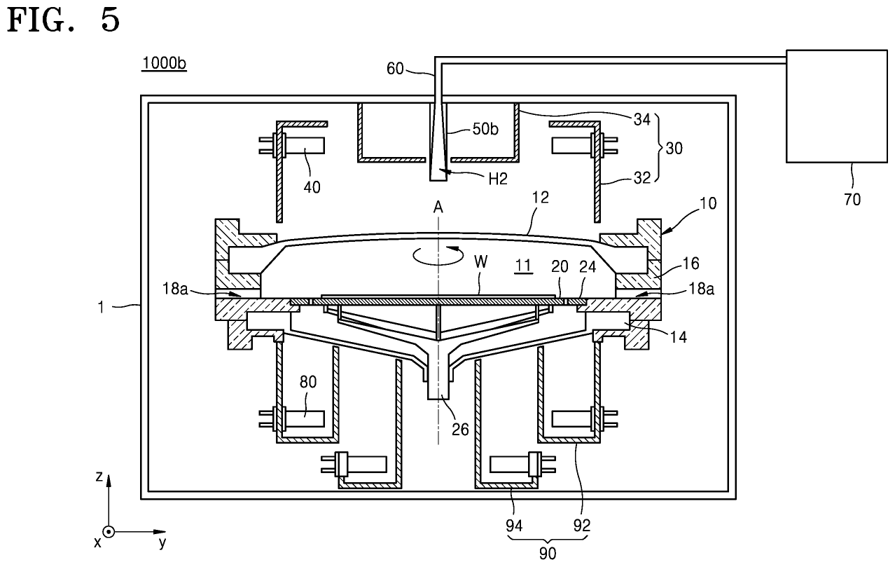

FIG. 5 is a schematic cross-sectional view of a thin-film deposition apparatus 1000b according to an embodiment.

Referring to FIG. 5, the thin-film deposition apparatus 1000b may include a housing 1, a chamber 10, a susceptor 20, a reflector 30, a light source unit 40, a light receiver 50b, an optical cable 60, and a sensor unit 70.

Optionally, the thin-film deposition apparatus 1000b may further include a lower reflector 90 and a lower light source 80.

Hereinafter, descriptions of the thin-film deposition apparatus 1000b that are redundant with those of the thin-film deposition apparatus 1000 of FIG. 1 will be omitted, and differences will be described.

The light receiver 50b of the thin-film deposition apparatus 1000b may have a hole H2. In an embodiment, the sensor unit 70 may be the OSA or multi-channel pyrometer described above.

The hole H2 of the light receiver 50b may have a tapered shape. In other words, a sidewall forming the hole H2 of the light receiver 50b may have an inclined shape. That is, the horizontal width of the hole H2 of the light receiver 50b may decrease as it approaches the optical cable 60. The horizontal width of the hole H2 of the light receiver 50b may decrease as the distance from the substrate W increases. For example, the horizontal width of the hole H2 of the light receiver 50b may decrease as it approaches the upper surface of the light receiver 50b.

In some embodiments, a sidewall forming the hole H2 of the light receiver 50b may be coated with a metal material. For example, an inner sidewall of the light receiver 50b may be coated with a material having high infrared reflectivity.

When the horizontal width of the hole H2 of the light receiver 50b decreases as it approaches the optical cable 60, the incident angle of light incident on the sidewall forming the hole H2 may increase. Accordingly, light incident on the light receiver 50b may be incident on the optical cable 60 with a relatively small number of reflections. As a result, light incident on the optical cable 60 may have relatively little noise.

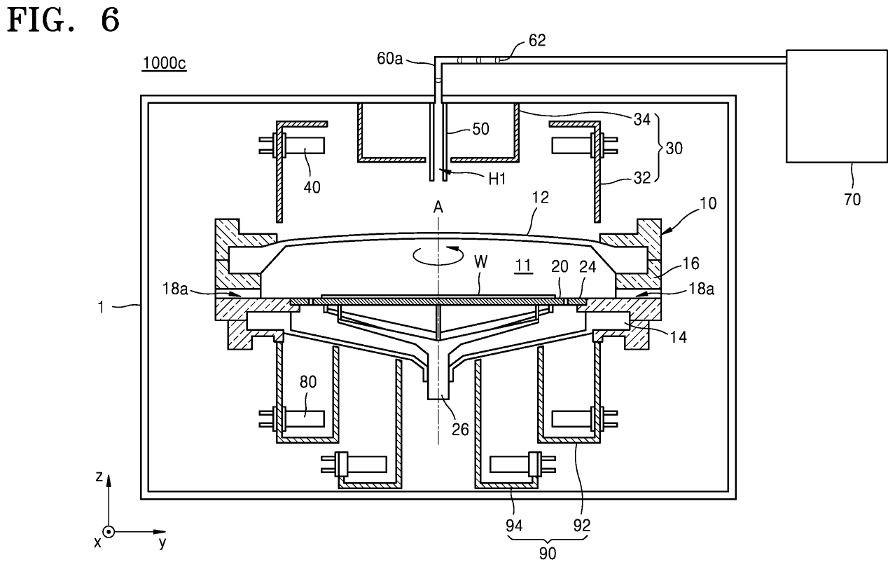

FIG. 6 is a schematic cross-sectional view of a thin-film deposition apparatus 1000c according to an embodiment.

Referring to FIG. 6, the thin-film deposition apparatus 1000c may include a housing 1, a chamber 10, a susceptor 20, a reflector 30, a light source unit 40, a light receiver 50, an optical cable 60a, and a sensor unit 70.

Optionally, the thin-film deposition apparatus 1000c may further include a lower reflector 90 and a lower light source unit 80.

Hereinafter, descriptions of the thin-film deposition apparatus 1000c that are redundant with those of the thin-film deposition apparatus 1000 of FIG. 1 will be omitted, and differences will be described.

The optical cable 60a of the thin-film deposition apparatus 1000c may include a plurality of lenses 62. The optical cable 60a may include a hollow portion therein, and the plurality of lenses 62 may be located in the hollow portion. The plurality of lenses 62 may be located on a path along which light incident on the optical cable 60a moves. The light introduced through the optical cable 60a may pass through the plurality of lenses 62 and be introduced into the sensor unit 70.

The plurality of lenses 62 may filter a certain wavelength of light having a continuous wavelength spectrum. For example, a certain wavelength of light incident on the optical cable 60a may not pass through the plurality of lenses 62 and may be absorbed or reflected by the plurality of lenses 62.

The plurality of lenses 62 may refract light incident on the optical cable 60a. For example, the plurality of lenses 62 may include at least one of a concave lens and a convex lens. Although all of the plurality of lenses 62 are shown as convex lenses in FIG. 6, the plurality of lenses 62 are not limited thereto and may include a convex lens and a concave lens.

Light incident on the optical cable 60a may have a continuous wavelength spectrum. As the light passes through the plurality of lenses 62 inside the optical cable 60a, a certain wavelength may be filtered. That is, the plurality of lenses 62 may transmit some wavelengths and absorb or reflect other wavelengths. Through the plurality of lenses 62, the sensor unit 70 may obtain a wavelength spectrum within a certain range, and thus, accurate analysis may be performed.

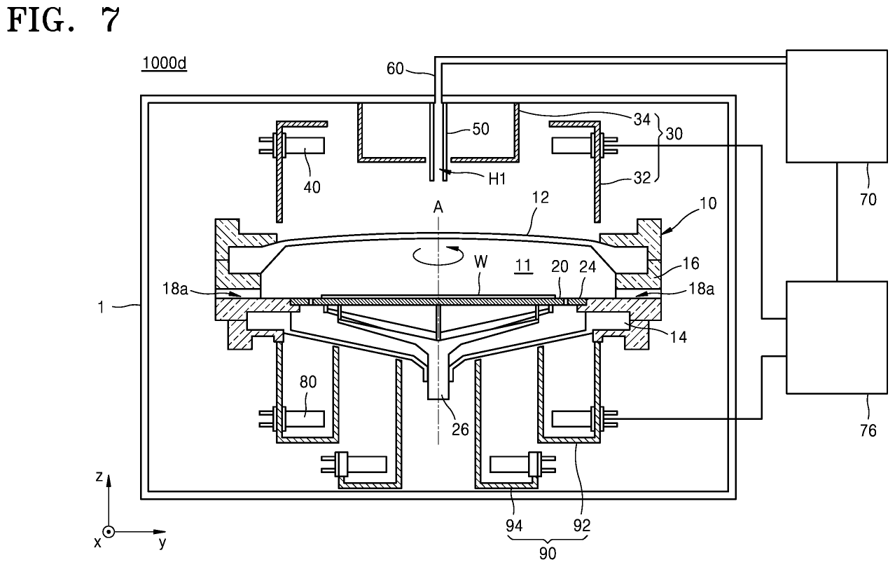

FIG. 7 is a schematic cross-sectional view of a thin-film deposition apparatus 1000d according to an embodiment.

Referring to FIG. 7, the thin-film deposition apparatus 1000d may include a housing 1, a chamber 10, a susceptor 20, a reflector 30, a light source unit 40, a light receiver 50, an optical cable 60, a sensor unit 70, and a temperature controller 76.

Optionally, the thin-film deposition apparatus 1000d may further include a lower reflector 90 and a lower light source unit 80.

Hereinafter, descriptions of the thin-film deposition apparatus 1000d that are redundant with those of the thin-film deposition apparatus 1000 of FIG. 1 will be omitted, and differences will be described.

The temperature controller 76 of the thin-film deposition apparatus 1000d may adjust the intensity of the light source unit 40. The temperature controller 76 may be located outside or inside the housing 1. The location of the temperature controller 76 may vary depending on facility environment. The temperature controller 76 may include a computer including input devices, processing devices, and storage, configured, for example, to allow a user or an automated process to set a desired temperature, and then to control the light source unit 40 and/or the lower light source unit 80 to control the temperature based on the setting.

The temperature controller 76 may be connected to the light source unit 40. Optionally, the temperature controller 76 may be connected to the lower light source unit 80. The temperature controller 76 may adjust the intensity of the light source unit 40 and the intensity of the lower light source unit 80. Accordingly, the temperature controller 76 may control the temperature of a substrate W by adjusting the intensity of the light source unit 40 and the intensity of the lower light source unit 80.

In some embodiments, the temperature controller 76 may be connected to the sensor unit 70. The temperature controller 76 may receive temperature information of the substrate W from the sensor unit 70. Based on the temperature of the substrate W, the temperature controller 76 may adjust the temperatures of the light source unit 40 and the lower light source unit 80. Therefore, the temperature controller 76 may be connected to the sensor unit 70 to feedback-control the temperatures of the light source unit 40 and the lower light source unit 80.

Specifically, the temperature controller 76 may reduce the intensity of the light source unit 40 when the temperature measured by the sensor unit 70 is higher than a process temperature, and may increase the intensity of the light source unit 40 when the temperature measured by the sensor unit 70 is lower than the process temperature.

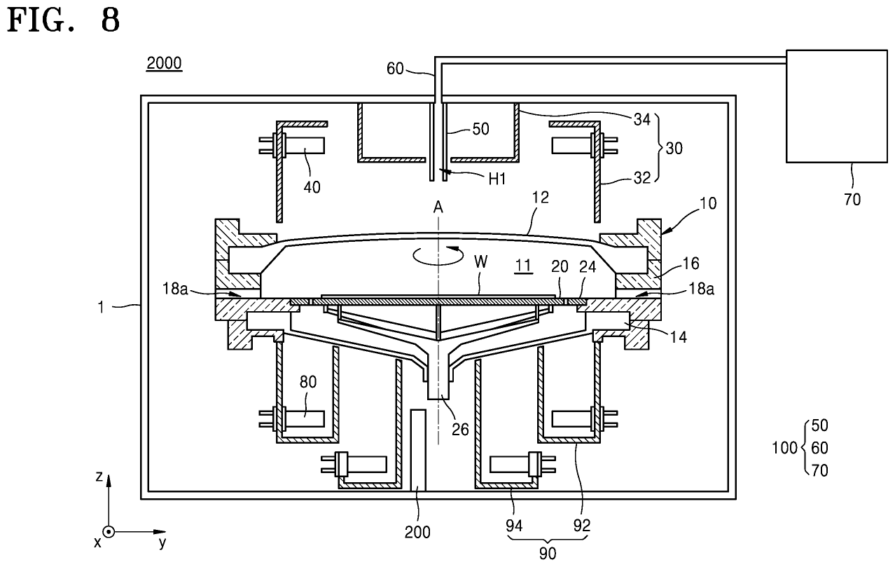

FIG. 8 is a schematic cross-sectional view of a thin-film deposition apparatus 2000 according to an embodiment.

Referring to FIG. 8, the thin-film deposition apparatus 2000 may include a housing 1, a chamber 10, a susceptor 20, a reflector 30, a light source unit 40, a first temperature measuring device 100, and a second temperature measuring device 200.

Optionally, the thin-film deposition apparatus 2000 may further include a lower reflector 90 and a lower light source 80.

The housing 1 may include the chamber 10, the susceptor 20, the reflector 30, and the light source unit 40 therein. The housing 1 may protect the chamber 10, the susceptor 20, the reflector 30, and the light source unit 40 from the outside.

The chamber 10 may be disposed within housing 1. The chamber 10 provides an internal space 11 in which a thin-film deposition process is performed on a substrate W. The chamber 10 may be an enclosed chamber and the internal space 11 may be controlled in a vacuum state. The chamber 10 may include an upper chamber 12, a lower chamber 14, and an edge ring 16. The upper chamber 12, the lower chamber 14, and the edge ring 16 may be coupled to each other to form the internal space 11. In some embodiments, the chamber 10 may include the chamber 10 (see FIG. 1) described with reference to FIG. 1.

The susceptor 20 is disposed within the chamber 10. Specifically, the susceptor 20 is disposed within the internal space 11. The susceptor 20 may support and rotate the substrate W. The susceptor 20 may include a graphite material or ceramic material coated with a silicon material, such as silicon carbide, or other process resistant material. In some embodiments, the susceptor 20 may include the susceptor 20 in FIG. 1.

The reflector 30 may be disposed within the housing 1. The reflector 30 may be disposed on an outer upper portion of the chamber 10. The reflector 30 may cover the upper chamber 12. The reflector 30 may include a first sub-reflector 32 and a second sub-reflector 34. The first sub-reflector 32 and the second sub-reflector 34 may be coupled to each other. In some embodiments, the reflector 30 may include the reflector 30 in FIG. 1.

The light source unit 40 may be disposed within the reflector 30. A plurality of light source units 40 may be provided. When the plurality of light source units 40 are provided, they may be arranged in a circumferential direction of the reflector 30. The light source unit 40 may be a halogen lamp. In some embodiments, the light source unit 40 may include the light source unit 40 in FIG. 1.

The first temperature measuring device 100 may include a first light receiver 50, a first optical cable 60, and a first sensor unit 70. The first temperature measuring device 100 may measure the temperature of the substrate W. Specifically, the first temperature measuring device 100 may measure the temperature and reflected energy of the substrate W.

The first light receiver 50 may be disposed within the housing 1. The first light receiver 50 may be spaced apart from the light source unit 40 with the reflector 30 therebetween. Light radiated by the light source unit 40 may not be directly introduced into the first light receiver 50. In some embodiments, the first light receiver 50 may be the previously described light receiver (i.e., the light receiver 50 in FIG. 1, the light receiver 50a in FIG. 4, or the light receiver 50b in FIG. 5).

In some embodiments, the first light receiver 50 may be located above the chamber 10. For example, the first light receiver 50 may receive light reflected or emitted from the upper surface of the substrate W.

The first optical cable 60 may connect the first light receiver 50 to the first sensor unit 70. Specifically, the first optical cable 60 may be connected to the hole H1 of the first light receiver 50. The first optical cable 60 may extend to the outside of the housing 1. That is, the first optical cable 60 may provide a path through which light introduced into the first light receiver 50 is transferred to the outside of the housing 1. In some embodiments, the first optical cable 60 may be the previously described optical cable (i.e., the optical cable 60 in FIG. 1 or the optical cable 60a in FIG. 6).

The first sensor unit 70 may be located outside the housing 1. For example, the first sensor unit 70 may be spaced apart from the light source unit 40 with the housing 1 therebetween. Specifically, heat generated by the light source unit 40 may be blocked by the housing 1 and may not reach the first sensor unit 70. As a result, when measuring the temperature of the substrate W, the temperature of the first sensor unit 70 may not substantially change due to the light source unit 40. In some embodiments, the first sensor unit 70 may be the previously described sensor unit (i.e., the sensor unit 70 in FIG. 1 or the sensor unit 70a in FIG. 3).

The second temperature measuring device 200, also described as a second temperature sensor, may measure the temperature of the substrate W. The second temperature measuring device 200 may be located inside the housing 1. The second temperature measuring device 200 may be disposed toward the bottom of the substrate W. The second temperature measuring device 200 may be disposed to correspond to the central axis A of the substrate W and be located on or adjacent to the central axis. The second temperature measuring device 200 may measure the temperature of a heating region of the substrate W. For example, the second temperature measuring device 200 may include a non-contact temperature sensor. For example, the second temperature measuring device 200 may be a pyrometer. According to an embodiment, a plurality of second temperature measuring devices 200 may be provided.

In some embodiments, the second temperature measuring device 200 may be a multi-channel pyrometer. The multi-channel pyrometer may include a head and an analyzer. The head may include a plurality of lenses and a plurality of sensors.

Specifically, light introduced into the second temperature measuring device 200 may be separated for each certain wavelength through the plurality of lenses in the head. Light including only a certain wavelength may be introduced into different sensors and the amount of light may be measured. The plurality of sensors may measure the amount of light of different wavelengths. The amount of light measured by the head may be transmitted to a sensor unit.

The sensor unit may measure the temperature and reflected energy of the substrate W through the amount of light at a certain wavelength. For example, the temperature and reflected energy of the substrate W may be measured through the temperature-wavelength relational expression.

In some embodiments, the first light receiver 50 of the first temperature measuring device 100 may be located above the chamber 10, and the second temperature measuring device 200 may be located below the chamber 10. For example, the first temperature measuring device 100 may measure light reflected or emitted from the upper surface of the substrate W, and the second temperature measuring device 200 may measure light reflected or emitted from the lower surface of the substrate W.

In the thin-film deposition apparatus 2000 according to the present embodiment, the temperature of the substrate W may be accurately measured by disposing temperature measuring devices above and below the chamber 10. In some embodiments, above the chamber 10, the first temperature measuring device 100 may measure the temperature of the substrate W, and below the chamber 10, the second temperature measuring device 200 may measure the temperature of the substrate W.

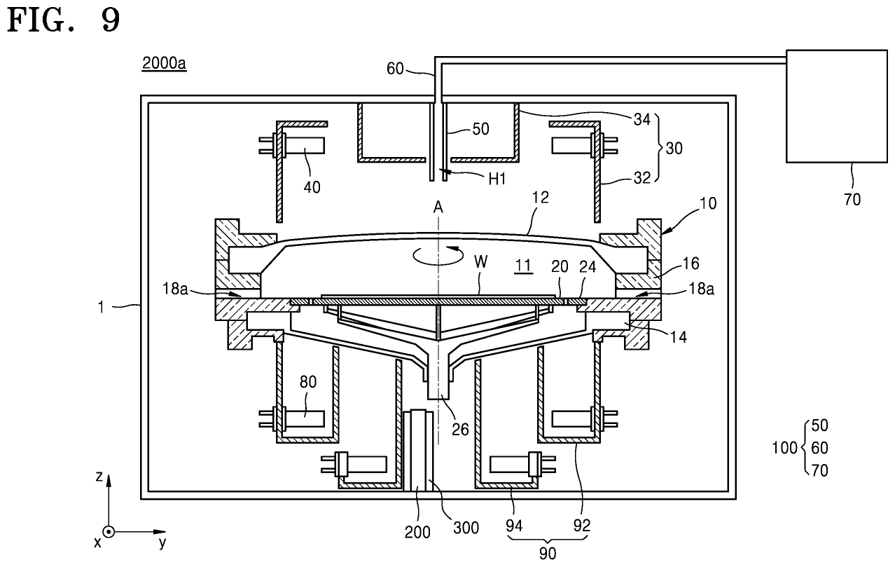

FIG. 9 is a schematic cross-sectional view of a thin-film deposition apparatus 2000a according to an embodiment.

Referring to FIG. 9, the thin-film deposition apparatus 2000a may include a housing 1, a chamber 10, a susceptor 20, a reflector 30, a light source unit 40, a first temperature measuring device 100, a second temperature measuring device 200, and a cooling device 300.

Hereinafter, descriptions of the thin-film deposition apparatus 2000a that are redundant with those of the thin-film deposition apparatus 2000 of FIG. 7 will be omitted, and differences will be described.

The cooling device 300 of the thin-film deposition apparatus 2000a may be installed in the second temperature measuring device 200. The cooling device 300 may control the temperature of the second temperature measuring device 200. In other words, because the second temperature measuring device 200 is inside the housing 1, the temperature of the second temperature measuring device 200 may be increased by the lower light source unit 80. Accordingly, the temperature of the second temperature measuring device 200 may be adjusted by installing the cooling device 300.

In some embodiments, the cooling device 300 may provide a path such that a cooling fluid introduced from the outside of the housing 1 flows around the second temperature measuring device 200. The cooling fluid flowing around the second temperature measuring device 200 may be discharged to the outside of the housing 1 along the path of the cooling device 300. Accordingly, the cooling device 300 may control the temperature of the second temperature measuring device 200 through the cooling fluid introduced from the outside of the housing 1.

In some embodiments, the cooling device 300 may include a heat dissipation wall. The heat dissipation wall of the cooling device 300 may cover a side surface of the second temperature measuring device 200. The heat dissipation wall may include a material having high thermal conductivity. The heat dissipation wall may suppress a phenomenon in which the temperature of the second temperature measuring device 200 is increased by the outside.

In the thin-film deposition apparatus 2000a according to the present embodiment, the cooling device 300 is installed in the second temperature measuring device 200 located inside the housing 1 to thereby improve the temperature measurement performance of the substrate W. By suppressing a phenomenon in which the temperature of the second temperature measuring device 200 located inside the housing 1 is increased by the light source unit 40 or the lower light source unit 80, the substrate temperature measurement performance of the second temperature measuring device 200 is improved.

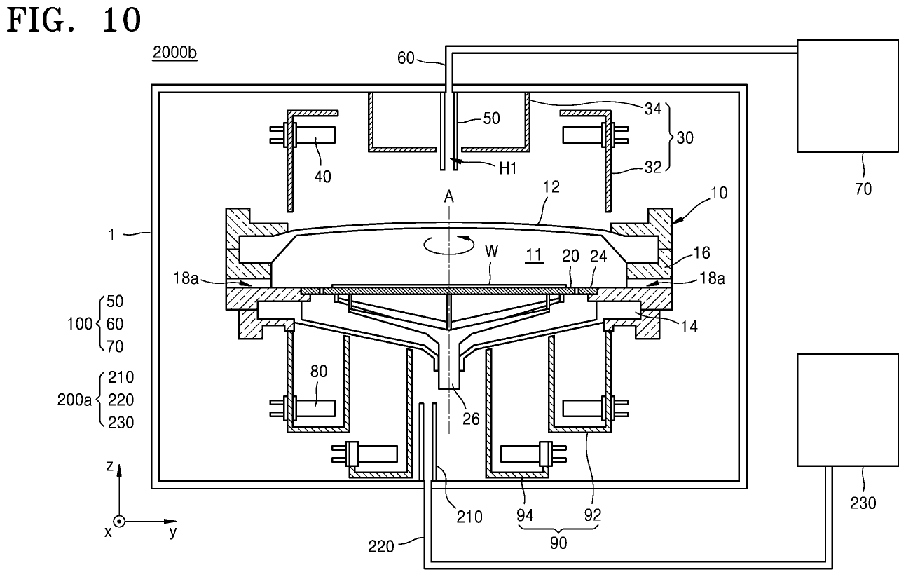

FIG. 10 is a schematic cross-sectional view of a thin-film deposition apparatus 2000b according to an embodiment.

Referring to FIG. 10, the thin-film deposition apparatus 2000b may include a housing 1, a chamber 10, a susceptor 20, a reflector 30, a light source unit 40, a first temperature measuring device 100, and a second temperature measuring device 200a.

Hereinafter, descriptions of the thin-film deposition apparatus 2000b that are redundant with those of the thin-film deposition apparatus 2000 of FIG. 7 will be omitted, and differences will be described.

The second temperature measuring device 200a of the thin-film deposition apparatus 2000b may include a second light receiver 210, a second optical cable 220, and a second sensor unit 230.

The second light receiver 210 of the second temperature measuring device 200a may be spaced apart from a lower light source unit 80 with a lower reflector 90 therebetween. Light radiated by the lower light source unit 80 may not be directly introduced into the second light receiver 210. The second light receiver 210 may collect light reflected or emitted from the lower surface of a substrate W.

In some embodiments, the second light receiver 210 may be spaced apart from the lower source unit 80 with the lower reflector 90 therebetween. The second light receiver 210 may be located above a bottom surface of the chamber 10.

In some embodiments, the second light receiver 210 may have a hole. In the hole, light reflected or emitted from the substrate W may be collected. That is, the hole may provide a path through which light reflected or emitted from the substrate W moves to the second optical cable 220.

In some embodiments, the second light receiver 210 may be the previously described light receiver (i.e., the light receiver 50 in FIG. 1, the light receiver 50a in FIG. 4, or the light receiver 50b in FIG. 5).

The second optical cable 220 of the second temperature measuring device 200a may be connected to the second light receiver 210. The second optical cable 220 may extend to the outside of the housing 1. Specifically, the second optical cable 220 may be connected to the hole of the second light receiver 210. The second optical cable 220 may provide a path through which light introduced into the second light receiver 210 is transferred to the outside of the housing 1.

In some embodiments, the second optical cable 220 may be the previously described optical cable (i.e., the optical cable 60 in FIG. 1 or the optical cable 60a in FIG. 6).

The second sensor unit 230 of the second temperature measuring device 200a may be disposed outside the housing 1. For example, the second sensor unit 230 may be spaced apart from the second light receiver 210 with the housing 1 therebetween. In this and other embodiments, an area for collecting light reflected or emitted from the substrate W may be different from an area for analyzing the light reflected or emitted from the substrate W.

The second sensor unit 230 may measure the temperature and reflected energy of the substrate W by analyzing light transmitted from the second optical cable 220. For example, the second sensor unit 230 may measure the temperature of the substrate W by analyzing light collected in the second light receiver 210.

In FIG. 10, the second sensor unit 230 of the second temperature measuring device 200a and the first sensor unit 70 of the first temperature measuring device 100 are spaced apart from each other and shown as separate components. However, the inventive concept is not limited thereto, and the first sensor unit 70 and the second sensor unit 230 may be adjacent to each other or integrated as one sensor device.

In some embodiments, the second sensor unit 230 may be the previously described sensor unit (i.e., the sensor unit 70 in FIG. 1 or the sensor unit 70a in FIG. 3).

As discussed herein, the temperature of a substrate may be measured through a hollow channel connected through a housing of a deposition apparatus such as a thin film deposition apparatus. The sensor for measuring the temperature may be connected to the channel, and may be located outside of the housing of the thin film deposition apparatus. The channel may include, for example, a light receiver portion connected to an optical cable portion. A plurality of light sources inside the housing and a plurality of reflectors inside the housing may be positioned to prevent light from entering the hollow channel directly from the light sources, but to allow light reflected or generated by the substrate to enter the hollow channel. In this manner, the temperature of the wafer can be determined remotely, from outside the housing, so that the heat internally generated inside the housing does not affect the temperature measurement made by the temperature sensor.

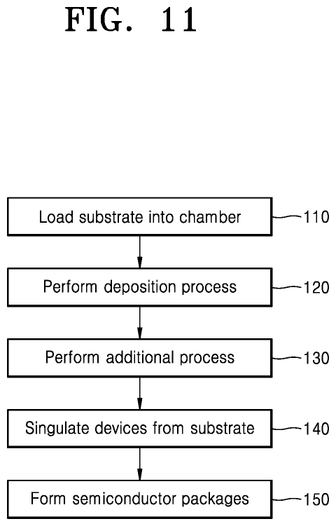

FIG. 11 is a flow chart for explaining a method of manufacturing a semiconductor device according to example embodiments. A semiconductor device may be, for example, a semiconductor chip including an integrated circuit formed on a die, which may be a memory chip, logic chip, or a processor chip. The semiconductor device may also be a semiconductor package including a package substrate, one or more semiconductor chips formed on the package, and an encapsulant covering the package substrate and the one or more semiconductor chips.

As one example, in step 110, a substrate is loaded into a chamber, such as chamber 10 in housing 1 of the various embodiments described previously. In step 120, a deposition process, such as a thin-film deposition, is performed. For example, a thin film formed of a monocrystalline, polycrystalline, or amorphous material (e.g., an epitaxial layer of Si, Ge, or SiGe) maybe formed on the substrate. Next, in step 130, a plurality of additional processes, such as a diffusion process, a heat treatment process, a photolithography process, a polishing process, an etching process, an ion implantation process, and a cleaning process may be carried out. These may be carried out in different chambers. The result of these processes may include a plurality integrated circuits on the substrate. For example, each integrated circuit may be a memory device or a logic device. In step 140, the devices may be singulated from the substrate to form individual semiconductor devices (e.g., chips). In step 150, the semiconductor devices may be packaged, for example, into a semiconductor package, for example, by placing each chip on a package substrate and forming an encapsulation layer to cover the chip and the package substrate.

While the inventive concept has been particularly shown and described with reference to embodiments thereof, it will be understood that various changes in form and details may be made therein without departing from the spirit and scope of the following claims.

What is claimed is:

1. A thin-film deposition apparatus comprising:
a housing;
a chamber located within the housing and providing an internal space;
a platform disposed within the chamber and configured to support a substrate;
a reflector disposed within the housing and disposed outside the chamber;
a light source disposed between opposing walls of the reflector and configured to radiate light onto the substrate;
a light receiver disposed within the housing, spaced apart from the light source with a portion of the reflector therebetween, and having a hole through which light emitted from the substrate is introduced;
an optical cable connected to the light receiver and extending to the outside of the housing; and
a sensor disposed outside the housing, connected to the optical cable, and configured to measure a temperature of the substrate by analyzing light transmitted from the optical cable.

2. The thin-film deposition apparatus of claim 1, wherein the light receiver is disposed above the chamber.

3. The thin-film deposition apparatus of claim 1, wherein the light receiver includes a transparent lens through which light radiated by the light source is transmitted.

4. The thin-film deposition apparatus of claim 1, wherein a horizontal width of the hole of the light receiver decreases as it approaches the optical cable.

5. The thin-film deposition apparatus of claim 1, wherein a metal is coated on a sidewall forming the hole of the light receiver.

6. The thin-film deposition apparatus of claim 1, further comprising a temperature controller configured to adjust intensity of the light radiated from the light source.

7. The thin-film deposition apparatus of claim 6, wherein the temperature controller is connected to the sensor to feedback-control the intensity of the light source.

8. The thin-film deposition apparatus of claim 1, wherein the optical cable includes a hollow portion, and a sidewall forming the hollow portion is coated with a metal.

9. The thin-film deposition apparatus of claim 1, wherein the optical cable includes a plurality of lenses disposed therein.

10. The thin-film deposition apparatus of claim 1, wherein the sensor is configured to receive light of consecutive wavelengths.

11. The thin-film deposition apparatus of claim 1, wherein the sensor is an optical spectrum analyzer.

12. The thin-film deposition apparatus of claim 1, wherein the sensor includes a plurality of channels, and the plurality of channels measure amounts of light of different wavelengths.

13. The thin-film deposition apparatus of claim 12, wherein the sensor further includes an analyzer configured to measure the temperature of the substrate based on measured values of the plurality of channels.

14. A thin-film deposition apparatus comprising:
a housing;
a chamber located within the housing and providing an internal space;
a susceptor disposed within the chamber and supporting a substrate;
a reflector disposed within the housing and disposed outside the chamber;
a light source disposed to be surrounded by the reflector and configured to radiate light onto the substrate;
a first temperature measuring device configured to measure a temperature of the substrate and including a first light receiver, a first optical cable, and a first sensor; and
a second temperature measuring device configured to measure the temperature of the substrate,
wherein the first light receiver is disposed within the housing, is spaced apart from the light source with the reflector therebetween, and has a hole through which light emitted from the substrate is introduced, the first optical cable extends to the outside of the housing to connect the first light receiver to the first sensor, and the first sensor is disposed outside the housing and configured to measure the temperature of the substrate by analyzing light transmitted from the first optical cable.

15. The thin-film deposition apparatus of claim 14, wherein the second temperature measuring device is located within the housing.

16. The thin-film deposition apparatus of claim 15, wherein the second temperature measuring device includes a multi-channel pyrometer.

17. The thin-film deposition apparatus of claim 16, further comprising a cooling device installed in the second temperature measuring device.

18. The thin-film deposition apparatus of claim 14, wherein the second temperature measuring unit includes a second light receiver, a second optical cable, and a second sensor,
wherein the second light receiver is disposed at a bottom of the housing and has a hole through which light emitted from the substrate is introduced, the second optical cable extends to the outside of the housing and is connected to the second sensor, and the second sensor is disposed outside the housing and is configured to measure the temperature of the substrate by analyzing light transmitted from the second optical cable.

19. The thin-film deposition apparatus of claim 14, wherein the first light receiver of the first temperature measuring device is located above the chamber, and the second temperature measuring device is located below the chamber.

20. A thin-film deposition apparatus comprising:
a housing;
a chamber disposed within the housing and providing an internal space;
a susceptor disposed within the chamber and supporting a substrate;
a reflector disposed within the housing and disposed outside the chamber;
a light source unit disposed within the reflector and configured to radiate light onto the substrate;
a first temperature measuring device configured to measure a temperature of the substrate and including a first light receiver, a first optical cable, and a first sensor unit;
a second temperature measuring device configured to measure the temperature of the substrate and located within the housing; and
a cooling device installed in the second temperature measuring device and configured to adjust a temperature of the second temperature measuring device,
wherein the first light receiver is disposed within the housing, is spaced apart from the light source unit with the reflector therebetween, and has a hole through which light emitted from the substrate is introduced, a sidewall forming the hole is coated with a reflective metal, and a horizontal width of the hole decreases as it approaches the first optical cable, the first optical cable extends to the outside of the housing to connect the first light receiver to the first sensor unit, and the first sensor unit is disposed outside the housing and configured to measure the temperature of the substrate by analyzing light of consecutive wavelengths transmitted from the first optical cable.
